(19) United States
(12) Patent Application Publication
(10) Pub. No.: US 2012/0014158 A1
(43) Pub. Date: Jan. 19, 2012

(54) MEMORY DEVICES

(75) Inventors: Ching-Wei WU, Caotun Town (TW); Cheng Hung LEE, Hsinchu (TW); Kuang Ting CHEN, Taipei City (TW)

(73) Assignee: TAIWAN SEMICONDUCTOR MANUFACTURING CO., LTD., Hsin-Chu (TW)

(21) Appl. No.: 12/838,572

(22) Filed: Jul. 19, 2010

(51) Int. Cl. G11C 17/12

(52) U.S. Cl. 365/104; 365/203

(57) ABSTRACT

A memory device includes an array of transistors, a plurality of bit lines, and a plurality of source lines. The transistors include gate, drain and source terminals. The gate terminals are electrically coupled to word lines. The plurality of bit lines connect a power source to the drain terminals of the array of transistors and the plurality of source lines connect the power source to the source terminals of the array of transistors. The connections are made active during a standby mode, thereby limiting leakage current without entailing drawbacks associated with degraded memory access/cycle time.

### TECHNICAL FIELD

The present invention relates generally to coupling electrical circuits, and more particularly to memory devices such as read-only memory (ROM) elements.

### BACKGROUND

In conventional high-speed ROM designs, the total current leakage is mainly contributed by the ROM bit cells, and can result in undesirable power consumption. Low-power ROM designs, such as designs involving a selective pre-charge scheme, may reduce the total current leakage compared to a conventional high-speed ROM design. However, low-power ROM designs typically have a slower access/cycle time than the conventional high-speed ROM design.

An improved memory device design would be desirable in the art.

### SUMMARY

A representative memory device includes an array of transistors, a plurality of bit lines, and a plurality of source lines. The array of transistors can include gate, drain and source terminals. The gate terminals are electrically coupled to word lines for selecting a number of bits. The plurality of bit lines connect a power source to the drain terminals of the array of transistors and the plurality of source lines connect the power source to the source terminals of the array of transistors during a standby mode. An object of the configuration is to obtain a low power consumption memory device wherein techniques for controlling power consumption do not cause the device to suffer from slow access/cycle time.

The above and other features of the present invention will be better understood from the following detailed description of certain exemplary embodiments of the invention, explained in connection with the accompanying drawings.

### BRIEF DESCRIPTION OF THE DRAWINGS

The accompanying drawings illustrate preferred embodiments of the invention, as well as other information pertinent to the disclosure, in which:

FIG. 1 is a block diagram that illustrates a system having a nonvolatile memory in accordance with an embodiment of the present disclosure;

FIG. 2 is a high-level block diagram that illustrates an embodiment of a nonvolatile memory, such as that shown in FIG. 1;

FIG. 3 is a schematic diagram that illustrates an embodiment of an array of bit cells of a nonvolatile memory, such as that shown in FIG. 2; and

FIG. 4 is an input-output waveform chart that illustrates an embodiment of operation of an array of bit cells, such as that shown in FIG. 3.

### DETAILED DESCRIPTION

This description of exemplary embodiments is intended to be read in connection with the accompanying drawings, which are to be considered part of the entire written description. Relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “coupled,” “connected” and “interconnected,” refer to a relationship wherein structures are secured or attached or operationally engaged with one another either directly or indirectly through intervening elements and structures, as well as both movable or switchable or rigid attachments or relationships, unless expressly described otherwise.

Exemplary systems are discussed with reference to the figures. Although these systems are described in detail, they are provided for purposes of illustration only and modifications are feasible within the scope of the subject matter defined in the appended claims.

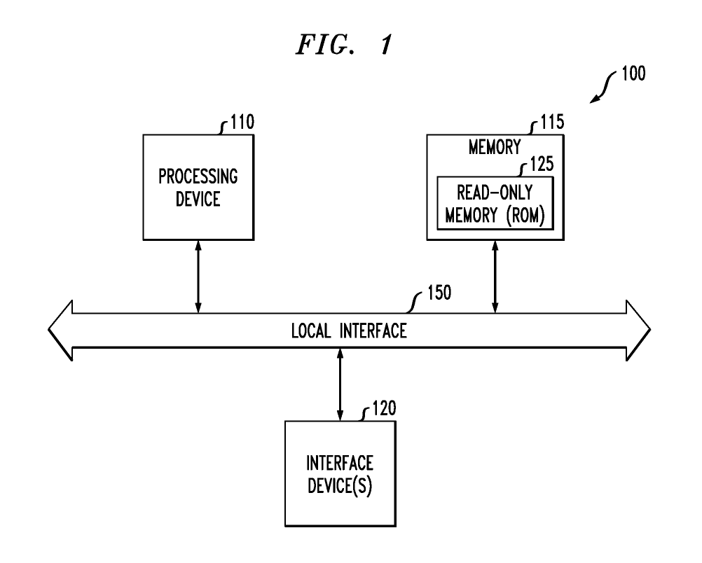

FIG. 1 is a block diagram that illustrates a system 100 having a nonvolatile memory 125 in accordance with an embodiment of the present disclosure. The system 100 exemplifies the general architecture of a generic computer. Specifically, the system 100 comprises a processing device 110, memory 115, and one or more interface devices such as user interface devices 120, which in this example are connected via a local interface 150 (e.g., a parallel bus). The processing device 110 can include a customized or commercially available processor, a central processing unit (CPU) or an auxiliary processor among several processors associated with the generic computer, a semiconductor based microprocessor (in the form of a microchip), or a macroprocessor. The memory 115 can be used for storing machine level instructions at addressable memory locations, and for reading and writing values, etc. Part of the memory is nonvolatile or read-only memory, i.e., ROM 125.

The one or more user interface devices 120 comprise those components whereby external entities such as a user can interact with the system 100. Where the system 100 comprises a server computer or similar device, these components can comprise those typically used in conjunction with a PC such as a keyboard and mouse.

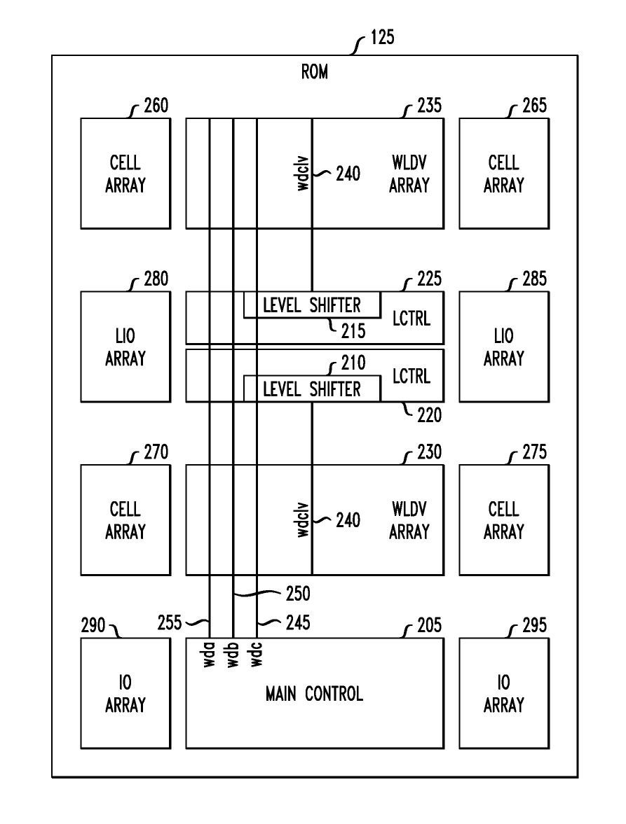

The memory 115 normally stores various programs and data values (in software and/or firmware) including an operating system (O/S). The O/S controls the execution of programs, and may provide scheduling, input-output control, file and data management, interrupt service routines, memory management, and communication control and related services. The memory 115 can include any combination of one or more volatile memory elements and registers (e.g., random access memory (RAM, such as DRAM, SRAM, etc.)) and more or less nonvolatile memory 125 (e.g., ROM, electrically programmable ROM, hard drive, tape, CDROM, etc.). The architecture of nonvolatile memory 125 is further described in connection with FIGS. 2-5.

FIG. 2 is a block diagram showing an exemplary nonvolatile memory element 125, such as that shown in FIG. 1. In this example, the nonvolatile memory 125 can be a read-only memory (ROM). The nonvolatile memory 125 includes a main control 205 that sends signals wda[N:0], wdb[M:0], and wdc[L:0] to word line driver arrays 230, 235 and the local control circuits 220, 225.

In general, the function of the main control 205 is to control operations of the memory 115 (FIG. 1), such as the read/write function, address pre-decode for the word line driver, chip enable/disable, self timing generation, and main input/output (I/O) array 290, 295 communication, among other functions and operations. The function of the local control circuits 220, 225 is to control local input/output (I/O) array 280, 285 for local bit line pre-charge, write pass gate, and sense amplifier enable, among other controls.

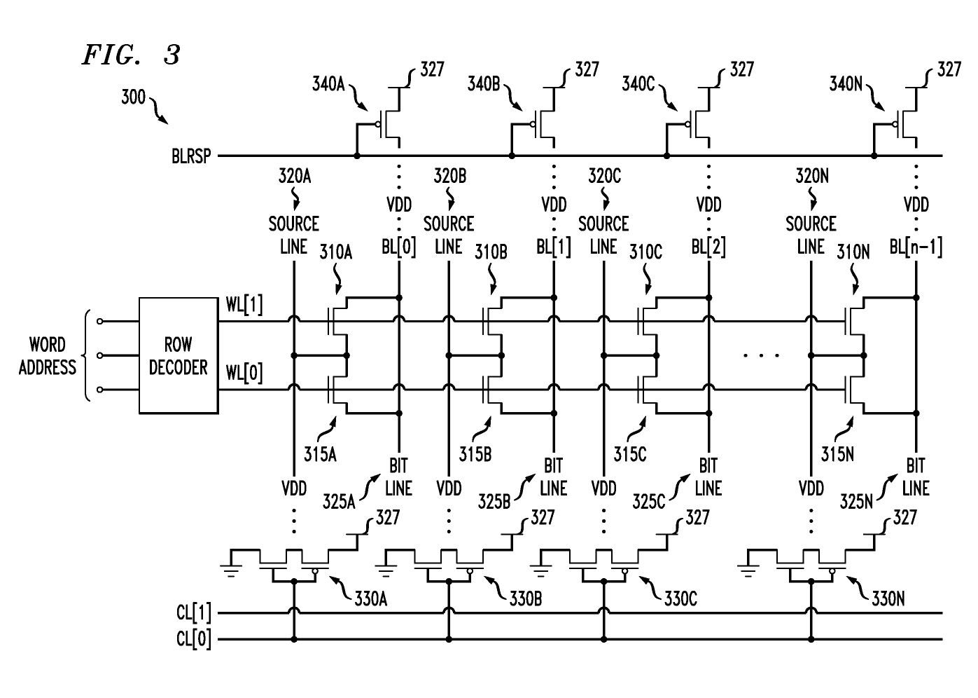

The local control circuits 220, 225 having level shifters 210, 215 that raise the address signal wdc[L:0] to a higher operating voltage in response to receiving a high signal (e.g., logical “1” state). The level shifters 210, 215 output shifted address signals to the word-line driver arrays 230, 235. The word line driver arrays 230, 235 process the address signals wda[N:0], wdb[M:0], wdc[L:0], wdclv for decoding at least one word line WL[1], WL[0] (FIG. 3) of the memory cell arrays 260, 265, 270, 275. The decoded word-line driver enables or turns on the word line WL[1], WL[0] for memory read or write operations. The word line driver arrays 230, 235 can further include decoder stages (not shown), respectively.

In this disclosure, the address signal wdc[L:0] causes the local control circuits 220, 225 and the word-line driver arrays 230, 235 to turn on or off the memory cell array 260, 265, 270, 275. The address signals wda[N:0], wdb[M:0] facilitate selecting the word lines WL[1], WL[0] at memory cell array 260, 265. Although the three address signals wda[N:0], wdb[M:0], wdc[L:0] are shown in FIG. 2, it will be appreciated by one skilled in the art that the disclosed circuitry and device can be implemented with any number of address signals, such as 8 or 16 address signals.

The local control circuits 220, 225 include respective level shifters 210, 215. The local control circuits 220, 225 use the local input output arrays 280, 285 to communicate with memory cell arrays 260, 265, 270, 275, respectively. Input output arrays 290, 295 are used to receive or send information stored in memory cell arrays 260, 265, 270, 275 to other electrical components such as the processing device 110 and/or user interface device 120 (FIG. 1). The local input output arrays 280, 285 and input output arrays 290, 295 are briefly mentioned to provide a system overview. The disclosure now focuses on certain embodiments of a memory device design as described, that are configured to maintain both favorable access/cycle time characteristics as well as low power consumption.

FIG. 3 is a schematic diagram that illustrates an embodiment of an array of bit cells 300 of a nonvolatile memory 125, such as that shown in FIG. 2. In this example, the array of bit cells 300 includes an array of transistors 310A-C, 310N, 315A-C, 315N, each having a gate, drain and source, coupled to corresponding terminals.

Word address—wda[N:0], wdb[M:0], wdc[L:0] (FIG. 2)—is received by a row decoder 335, which selects at least one of the word lines WL[1], WL[0] by raising the voltage at the selected word line WL[1], WL[0] based on the word address. The gate terminals of the respective transistors 310A-C, 310N, 315A-C, 315N are electrically coupled to the word lines WL[1], WL[0]. A plurality of bit lines 325A-C, 325N connect a power source 327 to the drain terminals of the array of transistors 310A-C, 310N, 315A-C, 315N and a plurality of source lines 320A-C, 320N connect the power source 327 to the source terminals of the array of transistors 310A-C, 310N, 315A-C, 315N during a standby mode.

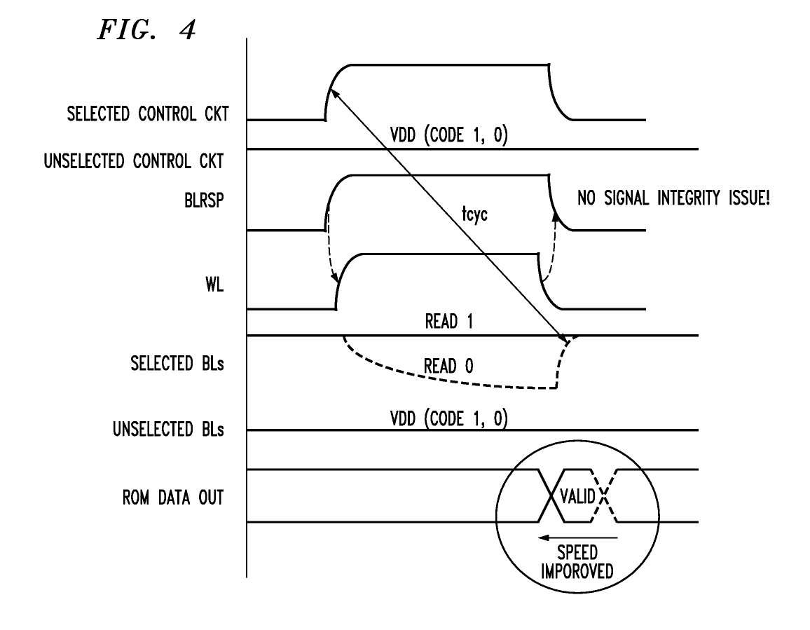

In general, by connecting the source lines 320 and the bit lines 325 to the power source 327 during the standby mode, the current leakage of the nonvolatile memory 125 (FIG. 2) can be reduced to a total standby current that is substantially less than characteristic of conventional nonvolatile memory designs. To reduce current leakage in a conventional memory design, a selective pre-charge scheme might be used, but the drawback of such a scheme is that it limits operational signal speed and can produce a low signal integrity situation. There is a tradeoff of due to the need to wait for the selective pre-charge period to elapse and pressing time constraints can leave an insufficient pulse width. The configuration of the presently disclosed embodiments is arranged to reduce this speed penalty and to relieve signal integrity issues, which is a challenge in a selective pre-charge scheme. Thus the operational signal speed and signal integrity of the embodiments of the present disclosure are comparable to the specifications of a conventional nonvolatile memory design, while leakage current is limited as comparable to a selective pre-charge scheme. These advantages are further clarified and described in connection with FIG. 4.

The pre-charge circuits 340A-C, 340N are electrically coupled to the plurality of bit lines 325A-C, 325N. In this example, the pre-charge circuits 340A-C, 340N include switch circuits, which can be implemented with PMOS transistors. The pre-charge circuits 340A-C, 340N couple the power source 327 to the plurality of bit lines 325A-C, 325N during a pre-charge period. The pre-charge circuits 340A-C, 340N receive bit-line pre-charge signals BSRSP from a local control 220, 225 (FIG. 2), which signals determine whether or not the bit lines 325A-C, 325N are pre-charged.

Control circuits 330A-C, 330N are electrically coupled to the plurality of source lines 320A-C, 320N. The control circuits 330A-C, 330N include inverter circuits that can connect the power source 327 to the plurality of source lines 320A-C, 320N during the standby mode. The inverter circuit connects a ground potential to the plurality of source lines 320A-C, 320N during an operational mode.

It should be noted that the plurality of source lines 320A-C, 320N are controlled by groups of 2, 4, 8 or any integer number by way of connecting said groups of the source lines 320A-C, 320N to the control circuits 330A-C, 330N. For example, groups of four (4) source lines 320A-C, 320N can be connected to the control circuits 330A-C, 330N that receives control signals from selected lines (e.g., SL[1] or SL[0]). Alternatively or additionally, groups of four (4) source lines 320A-C, 320N can be connected to respective control circuits 330A-C, 330N, where each control circuit 330 can control whether the four source lines 320A-C, 320N are connected to the power source 327 or potential ground.

It should be noted that “N” represents an indefinite and potentially large number. For purposes of discussion, it will be assumed that an unlimited number of combinations of the array of transistors 310, the plurality of bit lines 325 and a plurality of source lines 320 can be arranged in the nonvolatile memory 125.

In this example, at pre-charge mode, all source lines 320A-C, 320N and bit lines 325A-C, 325N are pre-charged to be at VDD (conventionally identifying the relatively more positive supply voltage in a field effect transistor or FET configuration). At operational mode, the inverter circuits 330A-C, 330N receive control signals at control lines (e.g., CL[0] or CL[1]) from a local control 220, 225 (FIG. 2) that determine whether the inverter circuits 330A-C, 330N are conducting or non-conducting. Responsive to receiving a “1” state, the inverter circuits 330A-C, 330N connect the source lines 320A-C, 320N to a ground potential to, and responsive to receiving a “0” state, the inverter circuits 330A-C, 330N connect the source lines 320A-C, 320N to the power source 327.

The selected bit cell 300 can be activated by both word line WL[1], WL[0] and bit line 325 and can start to an evaluation process. If the selected bit cell 300 stores a “0”, that means there is a discharge path from bit line 325 to source line 320 and the bit line state changes from VDD to be GND (or a different relatively more negative VSS voltage). If the selected bit cell 300 stores a “1”, that means there is no discharge path from bit line 325 to source line 320 and the bit line state remains at VDD. In general, a sensing circuit (not shown) detects the state (e.g., either VDD or GND) of the bit lines 325A-B, 325N, and transfers the data out of the selected bit cell 300 into some further register from which a logical or programmed operation ensues.

Although FIG. 3 shows PMOS and NMOS transistors, the array of bit cells 300 can be implemented with other transistors, such as CMOS, as can appreciated by one skilled in the art. It is also apparent that the control voltages are not required to be VDD and GND but can be VSS or Vcc.

FIG. 4 is an input-output waveform chart that illustrates an embodiment of operation of an array of bit cells 300 such as that shown in FIG. 3. In this example, the control circuit 330 can output either a “1” or “0” state, which represents whether a bit cell 300 has been selected or unselected, respectively. Responsive to the control circuit 330 being selected, the pre-charge circuit 340 charges the selected bit line 325 to VDD. The word line WL can go high when being activated. The word line WL generally does not affect whether the selected bit cell 300 is in Read0 or Read1 states. Read0 refers to a discharge path from a bit line 325 to a source line 320 and Read1 refers to no discharge path from bit line 325 to source line 320. The Read0 signal responds shortly after the control circuit 330 was selected, thereby reducing or eliminating signal speed penalty and low signal integrity.

The invention has been described in terms of certain exemplary embodiments and examples, but is not limited thereto. Rather, the appended claims should be construed broadly to include other variants and embodiments of the invention that may be made by those skilled in the art without departing from the scope and range of equivalents of the invention.

What is claimed is:

1. A read-only memory device comprising:
an array of transistors having gate, drain and source terminals, wherein the gate terminals are electrically coupled to word lines; and
a plurality of bit lines that connect a power source to the drain terminals of the array of transistors during a standby mode; and
a plurality of source lines that connect the power source to the source terminals of the array of transistors during the standby mode.

2. The read-only memory device of claim 1, further comprising at least one pre-charge circuit that is electrically coupled to the plurality of bit lines, wherein the at least one pre-charge circuit connects the power source to the plurality of bit lines during a pre-charge period.

3. The read-only memory device of claim 2, wherein the at least one pre-charge circuit includes a switch.

4. The read-only memory device of claim 1, further comprising at least one control circuit that is electrically coupled to the plurality of source lines, wherein the at least one control circuit connects the power source to the plurality of source lines during the standby mode.

5. The read-only memory device of claim 4, wherein the at least one control circuit includes an inverter circuit.

6. The read-only memory device of claim 5, wherein the inverter circuit connects a ground potential or a second power source to the plurality of source lines during an operational mode.

7. The read-only memory device of claim 4, wherein the plurality of source lines is configured to be controlled by groups of an integer number of said source lines by way of the at least one control circuit.

8. A memory device comprising:
at least one control circuit;
at least one input/output array that is electrically coupled to the at least one control circuit;
a plurality of bit lines that is electrically coupled to the at least one input/output array;
an array of transistors having gate, drain and source terminals, wherein the gate terminals are electrically coupled to word lines, wherein the plurality of bit lines connect a power source to the drain terminals of the array of transistors during a standby mode; and
a plurality of source lines that connect the power source to the source terminals of the array of transistors during the standby mode.

9. The memory device of claim 8, further comprising at least one pre-charge circuit that is electrically coupled to the plurality of bit lines, wherein the at least one pre-charge circuit connects the power source to the plurality of bit lines during a pre-charge period.

10. The memory device of claim 9, wherein the at least one pre-charge circuit includes a switch.

11. The memory device of claim 8, further comprising at least one control circuit that is electrically coupled to the plurality of source lines, wherein the at least one control circuit connects the power source to the plurality of source lines during the standby mode.

12. The memory device of claim 11, wherein the at least one control circuit includes an inverter circuit.

13. The memory device of claim 12, wherein the inverter circuit connects a ground potential or second power source to the plurality of source lines during an operational mode.

14. The memory device of claim 11, wherein the plurality of source lines is configured to be controlled by groups of any integer number by way of the at least one control circuit.

15. An integrated circuit comprising:
an array of transistors having gate, drain and source terminals, wherein the gate terminals are electrically coupled to word lines; and
a plurality of bit lines that connect a power source to the drain terminals of the array of transistors during a standby mode; and
a plurality of source lines that connect the power source to the source terminals of the array of transistors during the standby mode.

16. The integrated circuit of claim 15, further comprising at least one pre-charge circuit that is electrically coupled to the plurality of bit lines, wherein the at least one pre-charge circuit connects the power source to the plurality of bit lines during a pre-charge period.

17. The integrated circuit of claim 15, further comprising at least one control circuit that is electrically coupled to the plurality of source lines, wherein the at least one control circuit connects the power source to the plurality of source lines during the standby mode.

18. The integrated circuit of claim 17, wherein the at least one control circuit includes an inverter circuit.

19. The integrated circuit of claim 18, wherein the inverter circuit connects a ground potential to the plurality of source lines during an operational mode.

20. The integrated circuit of claim 17, wherein the plurality of source lines is configured to be controlled by groups of any integer number by way of the at least one control circuit.
